(19) United States
(12) Patent Application Publication
(10) Pub. No.: US 2022/0094159 A1
(43) Pub. Date: Mar. 24, 2022

(54) ELECTROSTATIC DISCHARGE PROTECTION CIRCUIT

(71) Applicant: HEXAWAVE Inc., Hsinchu (TW)

(72) Inventors: Shang-Hua TSAI, Hsinchu (TW); Te-Lin SUN, Hsinchu (TW); Yie-Der SHEN, Hsinchu (TW)

(21) Appl. No.: 17/198,215

(22) Filed: Mar. 10, 2021

(30) Foreign Application Priority Data
Sep. 24, 2020 (TW) 109133148

(51) Int. Cl. H02H 9/04; H01L 27/02

(52) U.S. Cl. CPC H02H 9/046; H01L 27/0266

(57) ABSTRACT

An electrostatic discharge protection circuit includes an input node, a ground node, a depletion mode transistor and an enhancement mode transistor. The enhancement mode transistor includes a gate contact, a drain contact, and a source contact. The source contact is connected to the gate contact by the depletion mode transistor. When the drain contact is connected to the input node, the source contact is connected to the ground node. When the source contact is connected to the input node, the drain contact is connected to the ground node.

### CROSS-REFERENCE TO RELATED APPLICATION

This application claims priority to Taiwan Application Serial Number 109133148, filed Sep. 24, 2020, which is herein incorporated by reference.

### BACKGROUND

### Field of Invention

The present disclosure relates to an electrostatic discharge protection circuit. More particularly, the present disclosure relates to an electrostatic discharge protection circuit including a depletion mode transistor.

### Description of Related Art

During the process of manufacturing, assembling, or testing semiconductor devices, static electricity often accumulates in the semiconductor devices, and therefore electrostatic discharge (ESD) occurs. The static electricity has a high voltage, a short discharge time, and a large instantaneous current. Therefore, the electrostatic discharge easily causes damage to the circuit function and reduces the yield of the semiconductor device.

Therefore, an electrostatic discharge protection circuit can be installed in a semiconductor device to protect the components and circuits in the semiconductor device from electrostatic discharge damage by conducting the electrostatic discharge current to the ground. However, the conventional electrostatic discharge protection circuit still has some disadvantages, such as large size. Therefore, there is an urgent need to develop a new electrostatic discharge protection circuit.

### SUMMARY

The present disclosure provides an electrostatic discharge protection circuit including an input node, a ground node, a depletion mode transistor, and an enhancement mode transistor. The enhancement mode transistor includes a gate contact, a drain contact, and a source contact. The source contact is connected to the gate contact by the depletion mode transistor. When the drain contact is connected to the input node, the source contact is connected to the ground node. When the source contact is connected to the input node, the drain contact is connected to the ground node.

In some embodiments, when a voltage of the input node is equal to or greater than a positive trigger voltage, the enhancement mode transistor turns on.

In some embodiments, when a voltage of the input node is equal to or less than a negative trigger voltage, the enhancement mode transistor turns on.

In some embodiments, the enhancement mode transistor is a metal semiconductor field-effect transistor or a high electron mobility transistor.

In some embodiments, the high electron mobility transistor is a transistor structure with multiple parallel gates.

The present disclosure provides an input node, a ground node, a first depletion mode transistor, a second depletion mode transistor, a first enhancement mode transistor, and a second enhancement mode transistor. The first enhancement mode transistor includes a first gate contact, a first drain contact, and a first source contact. The first drain contact is connected to the input node. The first source contact is connected to the first gate contact by the first depletion mode transistor. The second enhancement mode transistor includes a second gate contact, a second drain contact, and a second source contact. The second source contact is connected to the first source contact. The second gate contact is connected to the second source contact by the second depletion mode transistor. The second drain contact is connected to the ground node.

In some embodiments, the first enhancement mode transistor further includes a third gate contact, the third gate contact is connected to the first drain contact, the second enhancement mode transistor further includes a fourth gate contact, and the fourth gate contact is connected to the second drain contact.

In some embodiments, when a voltage of the input node is equal to or greater than a positive trigger voltage, the first enhancement mode transistor turns on.

In some embodiments, when a voltage of the input node is equal to or less than a negative trigger voltage, the second enhancement mode transistor turns on.

In some embodiments, the first enhancement mode transistor and the second enhancement mode transistor are independently a metal semiconductor field-effect transistor or a high electron mobility transistor.

In some embodiments, the high electron mobility transistor is a transistor structure with multiple parallel gates.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIGS. 1-4 are schematic diagrams of electrostatic discharge protection circuits in accordance with various embodiments of the present disclosure.

FIGS. 5-6 show schematic diagrams when the ESD protection circuit of FIG. 3 is triggered.

FIG. 7 is a schematic diagram of a depletion mode transistor and an enhancement mode transistor in an electrostatic discharge protection circuit in accordance with various embodiments of the present disclosure.

FIGS. 8-9 are current-voltage diagrams of electrostatic discharge protection circuits in accordance with various embodiments of the present disclosure.

### DETAILED DESCRIPTION

In order to make the description of the present disclosure more detailed and complete, please refer to the attached drawings and various embodiments described below. The same numbers in the drawings represent the same or similar elements.

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

The present disclosure provides a variety of electrostatic discharge protection circuits, and each includes an enhancement mode transistor and a depletion mode transistor embedded in the enhancement mode transistor. The depletion mode transistor has a small volume. Therefore, when the electrostatic discharge protection circuit is installed in the chip, it can save chip space, reduce manufacturing costs, and reduce power consumption.

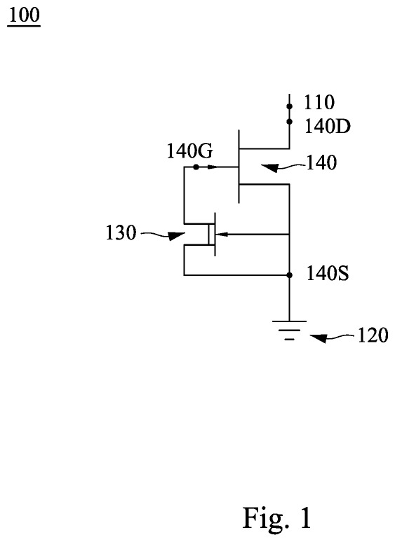

FIG. 1 is a schematic diagram of an electrostatic discharge protection circuit 100 in accordance with various embodiments of the present disclosure. The electrostatic discharge protection circuit 100 includes an input node 110, a ground node 120, a depletion mode field-effect transistor (D-FET) 130, and an enhancement mode field-effect transistor (E-FET) 140. The input node 110 is connected to a radio frequency (RF) circuit. The enhancement mode transistor 140 includes a gate contact 140G, a drain contact 140D, and a source contact 140S. The source contact 140S is connected to the gate contact 140G by the depletion mode transistor 130. The drain contact 140D is connected to the input node 110. The source contact 140S is connected to the ground node 120.

In some embodiments, the enhancement mode transistor 140 is a metal semiconductor field-effect transistor (MESFET) or a high electron mobility transistor (HEMT). For example, the enhancement mode transistor 140 is GaAs HEMT, GaN HEMT, GaAs MESFET, or GaN MESFET. For example, HEMT is a pseudomorphic high electron mobility transistor (pseudomorphic HEMT, pHEMT).

When the voltage between the input node 110 and the ground node 120 is in the normal operation mode, the enhancement mode transistor 140 is normally-off, so the electrostatic discharge protection circuit 100 is not conducting. In some embodiments, when electrostatic discharge occurs, when the voltage of the input node 110 is equal to or greater than the positive trigger voltage, the enhancement mode transistor 140 turns on, so that the electrostatic discharge current flows from the input node 110 to the ground node 120. In detail, when the positive voltage spike between the input node 110 and the ground node 120 is large enough, as the voltage approaches the gate-drain breakdown voltage, the leakage current through the drain contact 140D and the gate contact 140G may increase. This leakage current increases the voltage between the gate contact 140G and the source contact 140S to make it exceed the threshold voltage of the enhancement mode transistor 140. Therefore, the enhancement mode transistor 140 turns on, and the conducted enhancement mode transistor 140 can quickly conduct current from the input node 110 to the ground node 120 to protect the RF circuit from damage. The depletion mode transistor 130 acts as a constant current source, which limits the current flowing through the gate contact 140G.

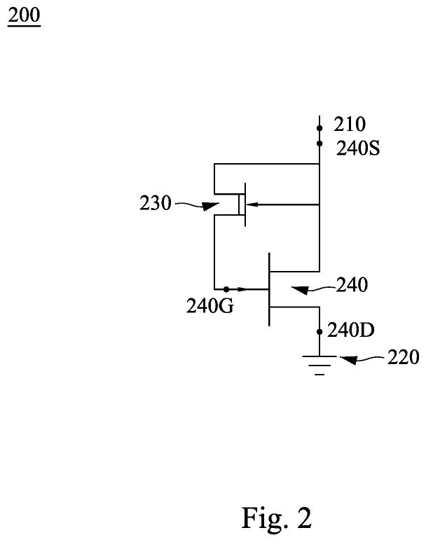

FIG. 2 is a schematic diagram of an electrostatic discharge protection circuit 200 in accordance with various embodiments of the present disclosure. The electrostatic discharge protection circuit 200 includes an input node 210, a ground node 220, a depletion mode transistor 230, and an enhancement mode transistor 240. The input node 210 is connected to the RF circuit. The enhancement mode transistor 240 includes a gate contact 240G, a drain contact 240D, and a source contact 240S. The source contact 240S is connected to the gate contact 240G by the depletion mode transistor 230. The source contact 240S is connected to the input node 210. The drain contact 240D is connected to the ground node 220. In some embodiments, the type of the enhancement mode transistor 240 can refer to the embodiment of the enhancement mode transistor 140, which will not be repeated here.

In some embodiments, when electrostatic discharge occurs, when the voltage of the input node 210 is equal to or less than the negative trigger voltage, the enhancement mode transistor 240 turns on, so that the electrostatic discharge current flows from the ground node 220 to the input node 210. In detail, when the negative voltage spike between the input node 210 and the ground node 220 is large enough, as the voltage approaches the gate-drain breakdown voltage, the leakage current through the drain contact 240D and the gate contact 240G may increase. This leakage current increases the voltage between the gate contact 240G and the source contact 240S to make it exceed the threshold voltage of the enhancement mode transistor 240. Therefore, the enhancement mode transistor 240 turns on, and the conducted enhancement mode transistor 240 can quickly conduct current from the ground node 220 to the input node 210 to protect the RF circuit from damage. The depletion mode transistor 230 acts as a constant current source, which limits the current flowing through the gate contact 240G.

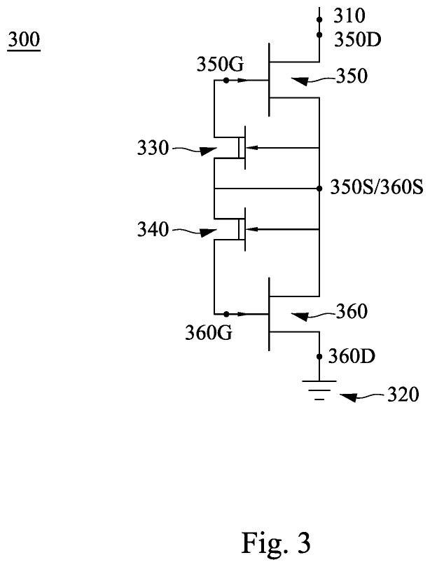

FIG. 3 is a schematic diagram of an electrostatic discharge protection circuit 300 in accordance with various embodiments of the present disclosure. The electrostatic discharge protection circuit 300 includes two sub-circuits connected back to back. Each sub-circuit includes a depletion mode transistor and an enhancement mode transistor. The depletion mode transistor is connected to the gate and the source of the enhancement mode transistor. In detail, the electrostatic discharge protection circuit 300 includes an input node 310, a ground node 320, a first depletion mode transistor 330, a second depletion mode transistor 340, a first enhancement mode transistor 350, and a second enhancement mode transistor 360. The first enhancement mode transistor 350 includes a first gate contact 350G, a first drain contact 350D, and a first source contact 350S. The first drain contact 350D is connected to the input node 310. The first source contact 350S is connected to the first gate contact 350G by the first depletion mode transistor 330. The second enhancement mode transistor 360 includes a second gate contact 360G, a second drain contact 360D, and a second source contact 360S. The second source contact 360S is connected to the first source contact 350S. The second gate contact 360G is connected to the second source contact 360S by the second depletion mode transistor 340. The second drain contact 360D is connected to the ground node 320. In some embodiments, the types of the first enhancement mode transistor 350 and the second enhancement mode transistor 360 can refer to the embodiment of the enhancement mode transistor 140, which will not be repeated here.

When the voltage between the input node 310 and the ground node 320 is in the normal operation mode, the enhancement mode transistors 350 and 360 are normally closed, so the electrostatic discharge protection circuit 300 is not conducting. In the normal operation mode, the enhancement mode transistors 350 and 360 can be regarded as capacitors, which cause the parasitic capacitance of the electrostatic discharge protection circuit 300. As shown in FIG. 3, the electrostatic discharge protection circuit 300 has two sets of clamp circuits connected in series, and the equivalent capacitance is about half of the capacitance of a single set of clamp circuit. The parasitic capacitance is an important parameter to measure the performance of electrostatic discharge protection circuit. The smaller the parasitic capacitance of the electrostatic discharge protection circuit is, the less the performance of the radio frequency circuit is affected. Therefore, manufacturers generally hope to reduce the parasitic capacitance of the electrostatic discharge protection circuit as much as possible. For example, if four clamping circuits are connected in series to form a circuit, its equivalent capacitance is about one-fourth of the capacitance of a single set of clamping circuit. However, the volume of this circuit is approximately twice the volume of the electrostatic discharge protection circuit 300.

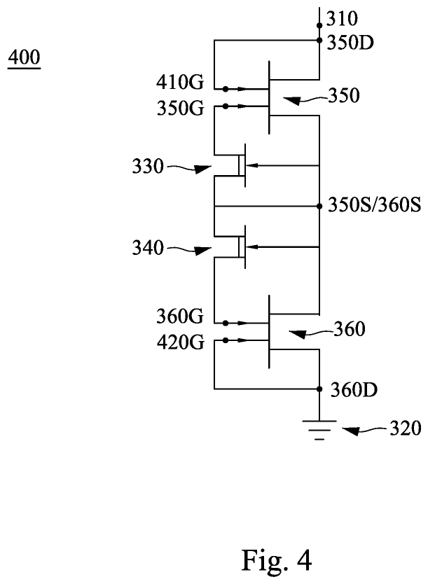

FIG. 4 is a schematic diagram of an electrostatic discharge protection circuit 400 in accordance with various embodiments of the present disclosure. The difference between the electrostatic discharge protection circuit 400 in FIG. 4 and the electrostatic discharge protection circuit 300 in FIG. 3 is that the electrostatic discharge protection circuit 400 further includes a third gate contact 410G and a fourth gate contact 420G. In detail, the first enhancement mode transistor 350 in FIG. 4 further includes a third gate contact 410G, and the third gate contact 410G is connected to the first drain contact 350D. The second enhancement mode transistor 360 in FIG. 4 further includes a fourth gate contact 420G, and the fourth gate contact 420G is connected to the second drain contact 360D.

As shown in FIG. 4, both the first enhancement mode transistor 350 and the second enhancement mode transistor 360 have a double gate structure. The volume of the electrostatic discharge protection circuit 400 is substantially the same as that of the electrostatic discharge protection circuit 300. However, the parasitic capacitance of the electrostatic discharge protection circuit 400 is approximately one-half of the parasitic capacitance of the electrostatic discharge protection circuit 300. Therefore, compared to the electrostatic discharge protection circuit 300, the electrostatic discharge protection circuit 400 is less likely to affect the performance of the radio frequency circuit.

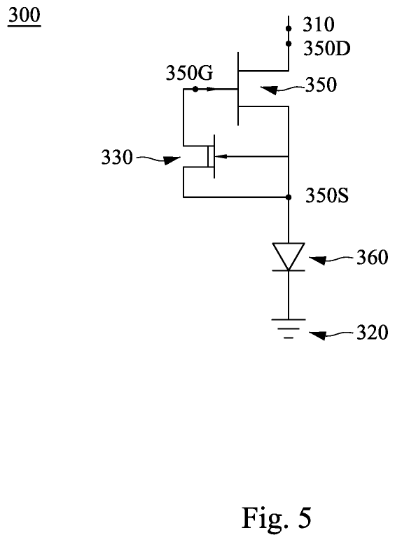

Next, please refer to FIG. 3 and FIG. 5 at the same time. FIG. 5 shows a schematic diagram of the electrostatic discharge protection circuit of FIG. 3 when it is triggered. In some embodiments, when electrostatic discharge occurs, when the voltage of the input node 310 is equal to or greater than the positive trigger voltage, the first enhancement mode transistor 350 turns on, as shown in FIG. 5. Therefore, the electrostatic discharge current flows from the input node 310 to the ground node 320. In detail, when the positive voltage spike between the input node 310 and the ground node 320 is large enough, as the voltage approaches the gate-drain breakdown voltage, the leakage current through the drain contact 350D and the gate contact 350G may increase. This leakage current increases the voltage between the gate contact 350G and the source contact 350S to make it exceed the threshold voltage of the enhancement mode transistor 350. Therefore, the enhancement mode transistor 350 turns on, and the conducted enhancement mode transistor 350 can quickly conduct current from the input node 310 to the ground node 320 to protect the RF circuit from damage. During the current flow, the second enhancement transistor 360 acts as a forward biased diode.

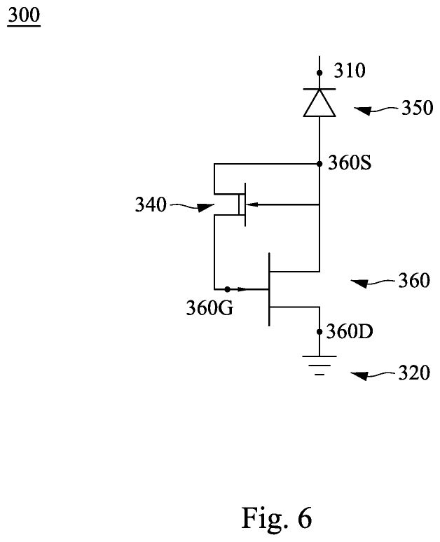

Next, please refer to FIG. 3 and FIG. 6 at the same time. FIG. 6 shows a schematic diagram of the electrostatic discharge protection circuit of FIG. 3 when it is triggered. In some embodiments, when electrostatic discharge occurs, when the voltage of the input node 310 is equal to or less than the negative trigger voltage, the second enhancement mode transistor 360 turns on, as shown in FIG. 6. Therefore, the electrostatic discharge current flows from the ground node 320 to the input node 310. In detail, when the negative voltage spike between the input node 310 and the ground node 320 is large enough, as the voltage approaches the gate-drain breakdown voltage, the leakage current through the drain contact 360D and the gate contact 360G may increase. This leakage current increases the voltage between the gate contact 360G and the source contact 360S to make it exceed the threshold voltage of the enhancement mode transistor 360. Therefore, the enhancement mode transistor 360 turns on, and the conducted enhancement mode transistor 360 can quickly conduct current from the ground node 320 to the input node 310 to protect the RF circuit from damage. During the current flow, the first enhancement mode transistor 350 acts as a forward biased diode.

It can be seen from FIGS. 5 and 6 that the electrostatic discharge protection circuit 300 of the present disclosure can protect the RF circuit from damage, when the voltage of the input node 310 is equal to or greater than the positive trigger voltage, or is equal to or less than the negative trigger voltage.

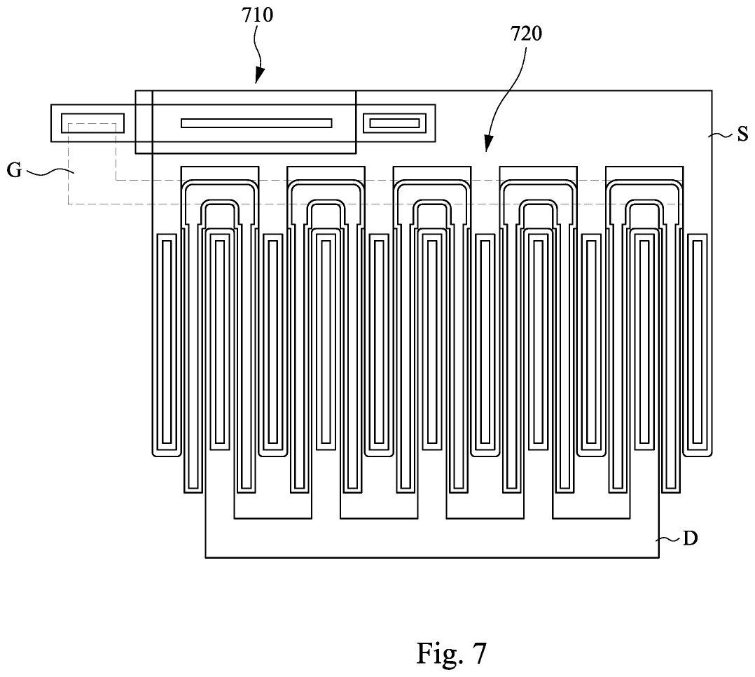

FIG. 7 is a schematic diagram of a depletion mode transistor 710 and an enhancement mode transistor 720 in an electrostatic discharge protection circuit in accordance with various embodiments of the present disclosure. The enhancement mode transistor 720 includes a gate G, a source S, and a drain D. The depletion mode transistor 710 is embedded in the source S of the enhancement mode transistor 720. The source S is connected to the gate G through the depletion mode transistor 710. Due to the small size of the depletion mode transistor 710, the size of the electrostatic discharge protection circuit can be reduced. As shown in FIG. 7, the enhancement mode transistor 720 is a transistor structure with multiple parallel gates.

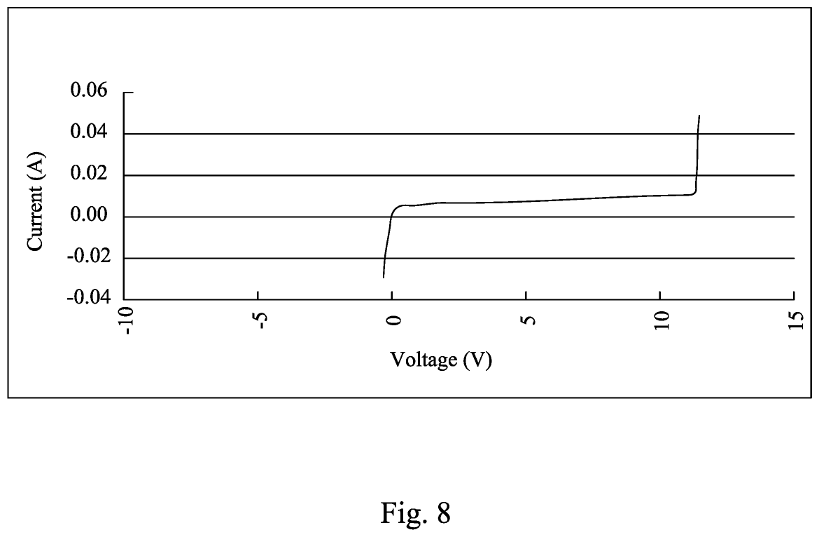

FIG. 8 is a current-voltage diagram of an electrostatic discharge protection circuit in accordance with various embodiments of the present disclosure. The structure of the electrostatic discharge protection circuit associates with the current-voltage diagram in FIG. 8 is shown as the electrostatic discharge protection circuit 100 in FIG. 1. As shown in FIG. 8, when the voltage input to the electrostatic discharge protection circuit 100 is equal to or greater than the positive trigger voltage, the enhancement mode transistor 140 turns on, and current flows through the electrostatic discharge protection circuit 100. When the voltage is less than the positive trigger voltage, the leakage current in the electrostatic discharge protection circuit 100 is very small.

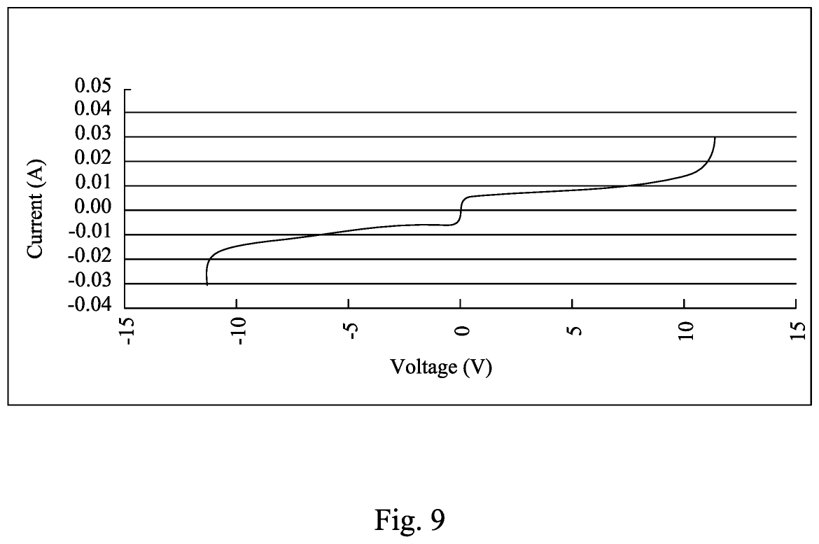

FIG. 9 is a current-voltage diagram of an electrostatic discharge protection circuit in accordance with various embodiments of the present disclosure. The structure of the electrostatic discharge protection circuit associates with the current-voltage diagram in FIG. 9 is shown as the electrostatic discharge protection circuit 300 in FIG. 3. As shown in FIG. 9, when the voltage input to the electrostatic discharge protection circuit 300 is equal to or greater than the positive trigger voltage, the first enhancement mode transistor 350 turns on, and current flows through the electrostatic discharge protection circuit 300. When the voltage input to the electrostatic discharge protection circuit 300 is equal to or less than the negative trigger voltage, the second enhancement mode transistor 360 turns on, and current flows through the electrostatic discharge protection circuit 300. When the voltage is less than the positive trigger voltage and greater than the negative trigger voltage, the leakage current in the electrostatic discharge protection circuit 300 is very small.

In summary, the present disclosure provides a variety of electrostatic discharge protection circuits, and each includes an enhancement mode transistor and a depletion mode transistor embedded in the enhancement mode transistor. Compared with electronic components such as resistors or diode strings, the depletion mode transistor has a smaller volume. Therefore, when the electrostatic discharge protection circuit is placed in the chip, it can save chip space and reduce manufacturing costs. In addition, the design of an enhancement mode transistor with double gates can reduce the parasitic capacitance of the electrostatic discharge protection circuit without increasing the volume of the electrostatic discharge protection circuit, thereby avoiding affecting the performance of the radio frequency circuit connected to the electrostatic discharge protection circuit.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electrostatic discharge protection circuit, comprising:
an input node;
a ground node;
a depletion mode transistor; and
an enhancement mode transistor comprising a gate contact, a drain contact, and a source contact,
wherein the source contact is connected to the gate contact by the depletion mode transistor,
when the drain contact is connected to the input node, the source contact is connected to the ground node, and
when the source contact is connected to the input node, the drain contact is connected to the ground node.

2. The electrostatic discharge protection circuit of claim 1, wherein when a voltage of the input node is equal to or greater than a positive trigger voltage, the enhancement mode transistor turns on.

3. The electrostatic discharge protection circuit of claim 1, wherein when a voltage of the input node is equal to or less than a negative trigger voltage, the enhancement mode transistor turns on.

4. The electrostatic discharge protection circuit of claim 1, wherein the enhancement mode transistor is a metal semiconductor field-effect transistor or a high electron mobility transistor.

5. The electrostatic discharge protection circuit of claim 4, wherein the high electron mobility transistor is a transistor structure with multiple parallel gates.

6. An electrostatic discharge protection circuit, comprising:
an input node;
a ground node;
a first depletion mode transistor;
a second depletion mode transistor;
a first enhancement mode transistor comprising a first gate contact, a first drain contact, and a first source contact, wherein the first drain contact is connected to the input node, and the first source contact is connected to the first gate contact by the first depletion mode transistor; and
a second enhancement mode transistor comprising a second gate contact, a second drain contact, and a second source contact, wherein the second source contact is connected to the first source contact, the second gate contact is connected to the second source contact by the second depletion mode transistor, and the second drain contact is connected to the ground node.

7. The electrostatic discharge protection circuit of claim 6, wherein the first enhancement mode transistor further comprises a third gate contact, the third gate contact is connected to the first drain contact, the second enhancement mode transistor further comprises a fourth gate contact, and the fourth gate contact is connected to the second drain contact.

8. The electrostatic discharge protection circuit of claim 6, wherein when a voltage of the input node is equal to or greater than a positive trigger voltage, the first enhancement mode transistor turns on.

9. The electrostatic discharge protection circuit of claim 6, wherein when a voltage of the input node is equal to or less than a negative trigger voltage, the second enhancement mode transistor turns on.

10. The electrostatic discharge protection circuit of claim 6, wherein the first enhancement mode transistor and the second enhancement mode transistor are independently a metal semiconductor field-effect transistor or a high electron mobility transistor.

11. The electrostatic discharge protection circuit of claim 10, wherein the high electron mobility transistor is a transistor structure with multiple parallel gates.
